(19) United States
(12) Patent Application Publication
(10) Pub. No.: US 2016/0111572 A1
(43) Pub. Date: Apr. 21, 2016

(54) Solar Panel Having Fire Protection

(71) Applicant: BASF SE, Ludwigshafen (DE)

(72) Inventor: Ralf Bohlander, Erkrath (DE)

(21) Appl. No.: 14/892,328

(22) PCT Filed: May 16, 2014
(86) PCT No.: PCT/EP2014/060073

§ 371 Date: Nov. 19, 2015

(30) Foreign Application Priority Data
May 27, 2013 (EP) 13169344.2

(51) Int. Cl. H01L 31/048

(52) U.S. Cl. CPC H01L 31/0488

(57) ABSTRACT

A fire-protected solar module comprises on an upper side a glass pane (1), thereunder a transparent encapsulant (2) with electrically connected solar cells embedded therein, thereunder a fire-protection module (3), with the proviso that the fire-protection module (3) is a laminated glass system made of plate glass with one or more intermediate layers made of an alkali metal silicate gel.

### FIELD OF THE INVENTION

The invention relates to the field of photovoltaic systems, and relates to a fire-protected solar module.

### PRIOR ART

Photovoltaic systems are solar power systems which use solar modules—also termed photovoltaic modules—to convert a portion of solar radiation to electrical energy. The modules are composed of solar cells connected in series or parallel, where the solar cells—also termed photovoltaic cells—are the electrical components in which the conversion from radiant energy to electrical energy is accomplished. Solar modules exist in flexible or rigid form; rigid solar modules are typically based on silicon-based solar cells mounted on an aluminum frame and covered by a sheet of glass. Photovoltaic systems use solar modules individually or in electrically connected groups.

Solar modules are typically structured as follows: (a) on the side facing toward the sun, a glass pane which inter alia serves for protection from hail and from contamination; the material known as toughened glass is frequently used here; (b) transparent plastics layer into which the solar cells have been embedded; (c) mono- or polycrystalline solar cells electrically connected to one another by solder strips; (d) a material laminated to the reverse side, using a weathering-resistant plastics composite film; (e) junction box involving freewheeling diode or bypass diode and connection terminal; (f) aluminum profile frame to protect the glass pane during transport, handling, and installation, and also for securing purposes, and to provide rigidity to the composite.

The term plate glass is generally used for glass in the form of panes—irrespective of the production process used. Plate glass is used by way of example in the automobile sector, for greenhouses, for windows, for mirrors, for display screens and computer displays, and for televisions and smart phones, and is also widely used in photovoltaic systems. Most of the plate glass used nowadays is float glass produced by the float process.

For fire-protection safety reasons, solar modules are attached on roofs at a distance from the roof tiles located thereunder. Nevertheless, there have been instances where short circuits due to overvoltages have led to destruction of entire roofs by fire.

### DESCRIPTION OF THE INVENTION

The object of the present invention consisted in providing a fire-protected solar module.

The invention firstly provides a fire-protected solar module comprising
on the upper side a glass pane (1),
thereunder a transparent encapsulant (2) with electrically connected solar cells embedded therein,
thereunder a fire-protection module (3), with the proviso that the fire-protection module (3) is a laminated glass system made of plate glass with one or more intermediate layers made of an alkali metal silicate gel.

The expression “upper side” of the solar module is defined in accordance with conventional usage as that side of the solar module that, after correct installation of the solar module, faces toward the sun during daytime. Correspondingly, the underside—also termed reverse side—of the solar module is the side opposite to the upper side.

For the purposes of the present invention, an alkali metal silicate gel is a composition which is composed of one or more alkali metal silicates and water and which per se has a viscosity of at least 10 000 mPas (measured with a Brookfield viscometer).

In one embodiment, the solar module of the invention also comprises a material laminated to the reverse side, using a weathering-resistant plastics composite film.

In one embodiment, the solar module of the invention is frameless.

In one embodiment the total weight of the solar module of the invention is less than 15 kg/m².

Glass Pane (1)

The glass pane (1) can per se be any desired glass. It is preferable to use transparent glass, in particular float glass. Very particular preference is given to transparent sodalime float glass with low iron content. One embodiment of the glass pane (1) has been coated from below with an alkali metal silicate.

Encapsulant (2)

An encapsulant is defined as an encapsulation material into which solar cells electrically connected to one another have been embedded. The encapsulant is selected from transparent materials. The material of which the encapsulant is composed is preferably a plastic, in particular a flexible plastic.

Fire-Protection Module (3)

The proviso stated above requires that the fire-protection module (3) is a laminated glass system made of plate glass (G) with one or more intermediate layers (Z) made of an alkali metal silicate gel. The simplest embodiment of the fire-protection module is therefore composed of the arrangement G-Z-G. However, it is also possible to use a plurality of intermediate layers, examples being embodiments with the arrangement G-Z-G-Z-G or G-Z-G-Z-G-Z-G.

It is preferable that the fire-protection module (3) is a plate glass with a single intermediate layer made of an alkali metal silicate gel. The plate glass here is in particular a float glass.

In one preferred embodiment, the thickness of the laminated glass system of the fire-protection module (3) is less than 3 mm, and in particular in the range from 0.8 to 2 mm.

In another preferred embodiment, the alkali metal silicate content of the alkali metal silicate gel comprised in the fire-protection module (3) is in the range from 50 to 80% by weight.

It is preferable that the alkali metal silicate comprised in the alkali metal silicate gel of the fire-protection module (3) is selected from the group of the lithium silicates, sodium silicates, and potassium silicates.

In one embodiment, the molar SiO₂:Alk₂O ratio (Alk=alkali metal) of the alkali metal silicate comprised in the fire-protection module (3) is in the range from 2 to 10. Particular preference is given here to sodium silicates and/or potassium silicates with molar SiO₂:Alk₂O ratio in the range from 3 to 6.

In one embodiment of the solar module of the invention, at least one glass element of the laminated glass system of the fire-protection module (3) was treated with alkali metal silicate in a layer thickness of from 10 to 150 nm before the production of the laminated glass system on the side facing toward the directly adjoining intermediate alkali metal silicate layer of the laminated glass system. A preferred method for this coating is that described in example 2 in the patent application WO 2012/037589 A2.

In one preferred embodiment, the fire-protection class of the fire-protection module (3) is to be at least EW30 (in accordance with EN 1363/1364).

In one embodiment, the glass comprised in the fire-protection module (3) is a colored glass.

### EXAMPLES

Substances Used

Demineralized water

Sodium silicate solutions and potassium silicate solutions (BASF)

Silica sols: Levasil (Eka Chemicals) or Klebosol (AZ-Chemie)

Glycerol=pharmaceutical-grade glycerol 99.8% (Pulcra).

Test Methods

The following tests used panes of float glass from f-glass (area=500 mm×500 mm, thickness=2 mm) and specifically in two variants: (i) untreated and (ii) treated by the coating method described in example 2 in the patent application WO 2012/037589 A2.

Alkali Corrosion Test:

Sheets of glass for fire-protection applications have to be alkali-resistant, because the pH of the fire-protection gels of the invention, in particular those based on potassium, is relatively high: about 12.

The glass samples were immersed in 1N KOH at 50° C. for 30 min, then washed with demineralized water; after air-drying, average spectral light transmittance was measured in accordance with DIN EN 410 as transparency TR30 (=transparency after 30 minutes) of the pane in comparison with initial transparency TRO. After removal of the glass sample, ICP trace analysis in aqueous alkali was used to test whether silica had dissolved from the glass; this provides a measure of corrosion; the ppm data determined in this IPC trace analysis indicate the quantity of SiO₂ transferred into the aqueous alkali by corrosion of the glass.

Untreated sodalime glass panes: TR0=91%/TR30=88%/ICP: 250 ppm of SiO₂

The following data were obtained from glass panes from the same production batch treated in accordance with the coating method described in example 1 in the patent application WO 2012/037589 A2 (another term also used below for this treatment being ARTT treatment):

TR0=92% TR30=91% ICP: 45 ppm of SiO₂

Water Film Test:

Background: During storage and/or transport a water film can form in an assembly of stacked glass panes, and if any change occurs to the glass said film could have an adverse effect elsewhere on the good adhesion of glass pane to polysilicate gel.

Method: The abovementioned glass-sheet samples were immersed in demineralized water for 24 h at room temperature. After drying, the panes were checked visually for changes, and transparency change was also checked.

No measurable change was observed in either of the two cases: in the case of the untreated glass (i) the values for TR0 (initial value) and TR24 (value determined after 24 hours) were respectively 91%, and in the case of the treated glass (ii) the values for TR0 and TR24 were respectively 92%.

Water Condensation Test:

The glass-sheet samples were stored at 60° C. and relative humidity 100% for 140 h and, after drying, assessed visually.

No measurable change was observed in either of the two cases: in the case of the untreated glass (i) the values for TR0 and TR140 (value determined after 140 hours) were respectively 91%, and in the case of the treated glass (ii) the values for TR0 and TR140 were respectively 92%.

### Production of Polysilicate Gels Based on Potassium Water Glass and Silica Sol

### Example

5 g of glycerol were stirred by an efficient stirring method at room temperature within a period of 10 minutes into 50 g of a highly concentrated potassium water glass solution 60 filtered to below 0.3 NTU (29% SiO₂, 31% K₂O, 40% H₂O) (BASF). 45 g of Klebosol 50R50 (50% SiO₂, 50% H₂O) (AZ-Chemie) were stirred into the mixture in a further period of 30 minutes by way of an immersed tube under pressure reduced to 0.1 bar. The viscosity of the finished liquid mixture remained low for about two hours at room temperature, and this mixture could be used as chemically curing casting composition.

(NTU: The so-called nephelometric turbidity unit (NTU) is a unit for turbidity. It is the unit for turbidity of a liquid, measured with a calibrated nephelometer (turbidity photometer). The standard on which this is based is EN ISO 7027.

### Example 2

2 g of glycerol were stirred by an efficient stirring method at room temperature within a period of 10 minutes into 50 g of a highly concentrated potassium water glass solution 55 filtered to below 0.3 NTU (32% SiO₂, 21% K₂O, 47% H₂O) (BASF). 53 g of Levasil 200A/40 (40% SiO₂, 60% H₂O) (Eka Chemicals) were stirred into the mixture in a further period of 30 minutes by way of an immersed tube under pressure reduced to 0.1 bar. The viscosity of the finished liquid mixture remained low for about one hour at room temperature, and this mixture could be used as chemically curing casting composition.

### Fire Tests

Fire tests were carried out in accordance with EN 1363/1364 with module dimensions 500 mm×500 mm with gel layer thickness 1.5 mm, with different polysilicate gels (gels according to examples 1 and 2), and the nature and thickness of the glass on either side of said polysilicate gels. Table 1 shows the results. Modules using the glass panes that were thinner, but pretreated, gave unchanged fire classifications.

TABLE 1
Fire classifications

| | 2 × 5 mm | | |
|---|---|---|---|
| | toughened | | 2 × 2 mm float glass |
| | glass | 2 × 2 mm float glass | (ARTT treated) |
| Gel of example 1 | EW 60 | EW 35 | EW 60 |
| Gel of example 2 | EW 60 | EW 45 | EW 60 |

N.B.: EW value data in table 1 are in accordance with the standard EN 1363/1364.

### Manufacture of Solar Modules

Glass-on-glass solar modules of the size that is conventional in the market, 1350 mm×1000 mm, with power rating about 190 Wp (Wp =Watt peak) were manufactured on a commercially available Lisec laminator, in accordance with operating instructions for same, from 24 crystalline Si solar cells (from the company Q-Cells) per module and EVA (ethylene-vinyl acetate, DuPont) or silicone resin (Tectosil, Wacker) with 2 mm ARTT-treated glass panes (from the company f-glass, processed in a Lisec HAL flatbed tempering system). In the case of half of the modules, a fire-protection layer based on the mixture of the above example 1 with a further 2 mm glass pane was also laminated to the reverse side.

Analogously dimensioned solar modules in accordance with the current standard available commercially in the market were produced with EVA (ethylene-vinyl acetate) encapsulant films (Elvax, DuPont) and plastics reverse side (S-type PV backsheet, Kaneka).

The resultant modules were adhesive-bonded with acrylic adhesive to a spruce wood roof-batten structure (thickness=2 cm, width=5 cm, distance between battens=20 cm).

Insolation at 1000 W was simulated by continuous illumination from xenon lamps. A steel strip of width 10 cm was placed obliquely onto the module surface to simulate shadowing and to induce a large voltage difference within the module and/or individual cell areas. Observation using a heat-imaging camera detected an initial uniform rise of module temperature to about 70° C. in the illuminated area of all of the modules. This was then followed, after some hours/days, by local temperature drops to about 50° C., and also isolated temperature increases above 100° C. to give “hot spots”. In the case of the commercially available modules used, some smoke generation, and shortly thereafter ignition/flames were observed, beginning at 200° C., but at the latest when a temperature of 250° C. was reached. The fire spread in all directions on the reverse side of the module, and also spread from there to the timber substructure. In the case of the modules produced in-house with EVA as encapsulant, glass cracks occurred at temperatures above 250° C. Here again, small flames appeared, and where the roof battens were close to the hot-spot locations the flames spread to the timber substructure. When modules reverse-side-laminated with fire-protection gel were used, in no case was there any impairment of the timber substructure. Results observed for Tectosil-encapsulated modules were only slight smoke generation at the module surface, and no flames.

1. A fire-protected solar module comprising:
on an upper side a glass pane,
thereunder a transparent encapsulant with electrically connected solar cells embedded therein,
thereunder a fire-protection module, with the proviso that the fire-protection module is a laminated glass system comprising a plate glass with one or more intermediate layers comprising an alkali metal silicate gel.

2. A fire-protected solar module comprising on the an upper side a glass pane, thereunder a transparent encapsulant with electrically connected solar cells embedded therein, thereunder a fire-protection module, with the proviso that the fire-protection module is a laminated glass system consisting of plate glass with one or more intermediate layers consisting of an alkali metal silicate gel.

3. The solar module according to claim 1, wherein the solar module further comprises a material laminated to a reverse side by a weather resistant plastics composite film.

4. The solar module according to claim 1, wherein the solar module is frameless.

5. The solar module according to claim 1, wherein the laminated glass system of the fire-protection module is the plate glass with a single intermediate layer comprising the alkali metal silicate gel.

6. The solar module according to claim 1, wherein the plate glass of the fire-protection module is a float glass.

7. The solar module according to claim 1, wherein a thickness of the laminated glass system of the fire-protection module is less than 3 mm.

8. The solar module according to claim 1, wherein an alkali metal silicate content of the alkali metal silicate gel is in the range of from 50 to 80% by weight.

9. The solar module according to claim 1, wherein a molar SiO₂:Alk₂O ratio, where Alk is an alkali metal, of the alkali metal silicate is in the range of from 2 to 10.

10. The solar module according to claim 8, wherein the alkali metal silicate is selected from the group consisting of: lithium silicates, sodium silicates, and potassium silicates.

11. The solar module according to claim 8, wherein at least one glass element of the laminated glass system of the fire-protection module is coated with an alkali metal silicate in a layer thickness of from 10 to 150 nm before the production of the laminated glass system on the side facing toward the directly adjoining intermediate layer comprising the alkali metal silicate gel of the laminated glass system.

12. The solar module according to claim 1, wherein a fire-protection class of the fire-protection module is at least EW30 in accordance with EN 1363/1364.

13. The solar module according to claim 1, where the glass pane is a float glass.

14. The solar module according to claim 13, wherein the glass pane has been coated from below with an alkali metal silicate.

15. The solar module according to claim 1, wherein the total weight of the solar module is less than 15 kg/m².

16. The solar module according to claim 2, wherein the solar module is frameless.

17. The solar module according to claim 2, wherein a fire-protection class of the fire-protection module is at least EW30 in accordance with EN 1363/1364.

18. The solar module according to claim 2, wherein the total weight of the solar module is less than 15 kg/m².
